(19) United States
(12) Patent Application Publication
(10) Pub. No.: US 2025/0169276 A1
(43) Pub. Date: May 22, 2025

(54) DISPLAY PANEL AND ELECTRONIC DEVICE

(71) Applicants: Yunnan Invensight Optoelectronics Technology Co., Ltd., Yunnan (CN); BOE Technology Group Co., Ltd., Beijing (CN)

(72) Inventors: Hongtao YU, Beijing (CN); Yuhao LEE, Beijing (CN); Weiliang BU, Beijing (CN); Dongdong SU, Beijing (CN); Hui TONG, Beijing (CN); Yunhao ZHANG, Beijing (CN); Zhongxiang YU, Beijing (CN); Zongshun YANG, Beijing (CN); Kuanta HUANG, Beijing (CN); Hui WANG, Beijing (CN)

(21) Appl. No.: 18/842,765

(22) PCT Filed: Sep. 27, 2023
(86) PCT No.: PCT/CN2023/122070

§ 371 Date: Aug. 29, 2024

(30) Foreign Application Priority Data
Nov. 15, 2022 (CN) 202211430260.3

(51) Int. Cl. H10K 50/17; H10K 59/122; H10K 59/80

(52) U.S. Cl. CPC H10K 50/17; H10K 59/122; H10K 59/80515

(57) ABSTRACT

A display panel and an electronic device are provided. The display panel has an inner cut-off region and a partition region adjacent to inner cut-off region. The display panel includes a substrate, a light-emitting layer, and a hole injection layer. The light-emitting layer is on the substrate. The hole injection layer is between the light-emitting layer and the substrate, and the light-emitting layer is on the hole injection layer and away from the substrate. The hole injection layer includes a first hole injection sub-portion in the partition region and a second hole injection sub-portion in the inner cut-off region and between the light-emitting layer and the substrate. A distance between the second hole injection sub-portion and the substrate is smaller than a distance between the first hole injection sub-portion and the substrate, and the first hole injection sub-portion is separated from the second hole injection sub-portion.

### TECHNICAL FIELD

The present application relates to display technology, and in particular to a display panel and an electronic device.

### BACKGROUND

In related technologies, micro-displays (e.g. Micro OLED (Organic Light-Emitting Diode) silicon-based micro-displays) are widely used as near-eye displays in the field of VR (Virtual Reality)/AR (Augmented Reality). As the market demand for high-brightness and low-power display panels increases, in the industry, two-layer light-emitting devices or three-layer light-emitting devices are often used to improve device efficiency and used as a product platform for product development and production.

However, the display panels of the micro-displays (e.g. Micro OLED silicon-based micro-displays) have the problem of substandard electrical crosstalk in a product.

### SUMMARY

The present application provides a display panel and an electronic device, to solve all or some of the deficiencies in the related technologies.

The first aspect of embodiments of the present application provides a display panel, where the display panel has an inner cut-off region and a partition region, and the inner cut-off region is adjacent to the partition region; the display panel includes: a substrate, a light-emitting layer, and a hole injection layer; a portion of the light-emitting layer in the inner cut-off region is configured to emit lights, and the light-emitting layer is on the substrate; the hole injection layer is between the light-emitting layer and the substrate, and the light-emitting layer is on the hole injection layer and away from the substrate; the hole injection layer includes a first hole injection sub-portion and a second hole injection sub-portion; the first hole injection sub-portion is in the partition region; the second hole injection sub-portion is in the inner cut-off region and between the light-emitting layer and the substrate; and a distance between the second hole injection sub-portion and the substrate is smaller than a distance between the first hole injection sub-portion and the substrate, and the first hole injection sub-portion is separated from the second hole injection sub-portion.

In some embodiments, the display panel further includes an anode; the anode is at least partially in the inner cut-off region, the anode is between the hole injection layer and the substrate, and the anode is between the second hole injection sub-portion and the substrate; and where the anode is electrically connected with the second hole injection sub-portion.

In some embodiments, the display panel further includes a step structure, and the step structure is between the first hole injection sub-portion and the substrate; and where the first hole injection sub-portion is on the step structure and away from the substrate, and the step structure includes at least one step; and a portion of the second hole injection sub-portion is on a surface of the at least one step and away from the substrate, and the step structure is configured to ensure that second hole injection sub-portions on the at least one step away from the substrate are separated from each other and that the first hole injection sub-portion is separated from the second hole injection sub-portions.

In some embodiments, the step includes an inner recess, and the inner recess is a portion of the step being recessed along a direction from the inner cut-off region towards the partition region; the inner recess is between the step and the second hole injection sub-portion; and the inner recess is arranged corresponding to the second hole injection sub-portion.

In some embodiments, the display panel further includes: at least two light-emitting layers and at least one charge generation layer; each of the at least two light-emitting layers and the at least one charge generation layer is on the hole injection layer away from the substrate; and where each of the at least one charge generation layer includes a first charge generation sub-portion and a second charge generation sub-portion; the first charge generation sub-portion is in the partition region; the second charge generation sub-portion is in the inner cut-off region; in a direction away from the substrate, the light-emitting layer and the second charge generation sub-portion are arranged alternately, and in the direction away from the substrate, both a first film layer and a last film layer are the light-emitting layers; and a distance between the second charge generation sub-portion and the substrate is smaller than a distance between the first charge generation sub-portion and the substrate, and the first charge generation sub-portion is separated from the second charge generation sub-portion.

In some embodiments, the display panel further includes a step structure, and the step structure is between the first hole injection sub-portion and the substrate; where the first hole injection sub-portion is on the step structure and away from the substrate, and the step structure includes at least one step; a portion of the second hole injection sub-portion is on a surface of the at least one step and away from the substrate, and the step structure is configured to ensure that second hole injection sub-portions on the at least one step away from the substrate are separated from each other and that the first hole injection sub-portion is separated from the second hole injection sub-portions; and the second charge generation sub-portion is on the second hole injection sub-portion and away from the substrate, and a portion of the second charge generation sub-portion is on the at least one step and away from the substrate; and the step structure is configured to ensure that the second charge generation sub-portions on the at least one step away from the substrate are separated from each other and that the first hole injection sub-portion is separated from the second hole injection sub-portions.

In some embodiments, a total quantity of layers of the hole injection layer and the charge generation layer is the same as a quantity of the steps; and one layer of the hole injection layer or one layer of the charge generation layer is arranged corresponding to one of the steps.

In some embodiments, each of the steps includes an inner recess, and the inner recess is a portion of the step being recessed along a direction away from the inner cut-off region; and the inner recess is between the step and the second hole injection sub-portion corresponding to the step, or, the inner recess is between the step and the second charge generation sub-portion corresponding to the step.

In some embodiments, the step structure includes an inner cut portion in the inner cut-off region, and the inner cut portion is a portion of the step structure being recessed towards the substrate; and the step in the inner cut portion is configured to separate at least one layer of the second hole injection sub-portion or the second charge generation sub-portion.

In some embodiments, the step provided in adjacent inner cut-off regions separates at least one layer of the second hole injection sub-portion or the second charge generation sub-portion.

The second aspect of embodiments of the present application provides an electronic device including any one of the display panel described above.

It can be learned from embodiments of the present application that, the second hole injection sub-portion is in the inner cut-off region, the first hole injection sub-portion is in the partition region, the distance between the second hole injection sub-portion in the inner cut-off region and the substrate is smaller than the distance between the first hole injection sub-portion in the partition region and the substrate, and the first hole injection sub-portion is separated from the second hole injection sub-portion. Thus, the portions of the hole injection layer in different regions are not on the same plane, i.e., the first hole injection sub-portion in the partition region and the second hole injection sub-portion in the inner cut-off region are not on the same plane, such that the first hole injection sub-portion and the second hole injection sub-portion form a “recess”-shaped structure. Furthermore, since the portions of the hole injection layer in different regions are not on the same plane, there is a height difference between the first hole injection sub-portion and the second hole injection sub-portion in the second direction Z. Due to the exist of the height difference, when the first hole injection sub-portion and the second hole injection sub-portion are formed, the first hole injection sub-portion and the second hole injection sub-portion can be separated without being electrically connected, therefore, through a “recess”-shaped structure formed by the first hole injection sub-portion and the second hole injection sub-portion, the current flowing in the hole injection layers having an electrical connection relationship between the sub-pixels may be blocked. Further, it may avoid crosstalk between the currents generated by the respective hole injection layers of sub-pixels, thereby avoiding the problem of lateral current leakage between respective sub-pixels, and it may avoid the problem of substandard electrical crosstalk and low color gamut in a product caused by lateral current leakage between respective sub-pixels.

It should be understood that the above general descriptions and the following detailed descriptions are merely for exemplary and explanatory purposes, and cannot limit the present application.

### BRIEF DESCRIPTION OF DRAWINGS

The accompanying drawings are incorporated in the present description and constitute a part of the present description, illustrate embodiments consistent with the present application, and serve to explain the principles of the present application together with the present description.

FIG. 1 is a structure diagram of a display panel according to embodiments of the present application;

FIG. 2 is a structure diagram of a light-emitting unit of a display panel according to embodiments of the present application;

FIG. 3 is a structure diagram of another display panel according to embodiments of the present application.

### DETAILED DESCRIPTION

Embodiments will be described in detail here, examples of which are illustrated in the accompanying drawings. When the following description relates to the accompanying drawings, unless specified otherwise, the same numerals in different drawings represent the same or similar elements. The implementations described in the following embodiments do not represent all implementations consistent with the present application. Rather, they are merely examples of apparatuses and methods consistent with some aspects of the present application as detailed in the appended claims.

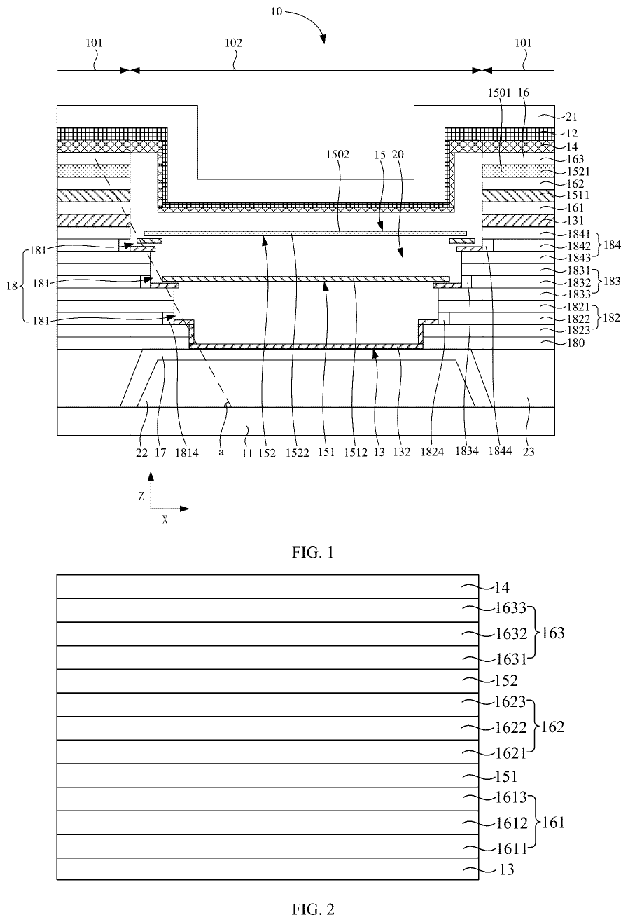

Embodiments of the present application provides a display panel 10. FIG. 1 illustrates a structure diagram of the display panel 10. As illustrated in FIG. 1, the display panel 10 has an inner cut-off region 102 and a partition region 101. The inner cut-off region 102 is adjacent to the partition region 101.

The display panel 10 includes a substrate 11, a light-emitting layer 16, and a hole injection layer 13.

A portion of the light-emitting layer 16 in the inner cut-off region 102 is configured to emit lights, and the light-emitting layer 16 is on the substrate 11. The hole injection layer 13 is between the light-emitting layer 16 and the substrate 11, and the light-emitting layer 16 is on the hole injection layer 13 and away from the substrate 11.

The hole injection layer 13 includes a first hole injection sub-portion 131 and a second hole injection sub-portion 132. The first hole injection sub-portion 131 is in the partition region 101. The second hole injection sub-portion 132 is in the inner cut-off region 102 and between the light-emitting layer 16 and the substrate 11. A distance between the second hole injection sub-portion 132 and the substrate 11 is smaller than a distance between the first hole injection sub-portion 131 and the substrate 11, and the first hole injection sub-portion 131 is separated from the second hole injection sub-portion 132.

In some embodiments, FIG. 1 illustrates a first direction X and a second direction Z. The second direction Z is a direction away from the substrate 11. In the display panel 10, the partition region 101 is adjacent to the inner cutting area 102 in the first direction X.

The distance between the first hole injection sub-portion 131 and the substrate 11 is, in the second direction Z, the distance between the first hole injection sub-portion 131 and the substrate 11. Similarly, the distance between the second hole injection sub-portion 132 and the substrate 11 is, in the second direction Z, the distance between the second hole injection sub-portion 132 and the substrate 11. The distance between the second hole injection sub-portion 132 and the substrate 11 is smaller than the distance between the first hole injection sub-portion 131 and the substrate 11, that is, in the second direction Z, the second hole injection sub-portion 132 is closer to the substrate 11 than the first hole injection sub-portion 131. Due to the fact that in the second direction Z, the second hole injection sub-portion 132 is closer to the substrate 11 than the first hole injection sub-portion 131, the portions of the hole injection layer 13 in different regions are not on the same plane, i.e., the first hole injection sub-portion 131 in the partition region 101 and the second hole injection sub-portion 132 in the inner cut-off region 102 are not on a same plane. Thus, there is a height difference between the first hole injection sub-portion 131 and the second hole injection sub-portion 132 in the second direction Z. Due to the exist of the height difference in the second direction Z, when the first hole injection sub-portion 131 and the second hole injection sub-portion 132 are formed, the first hole injection sub-portion 131 and the second hole injection sub-portion 132 can be separated without being electrically connected. It should be noted that, the plane mentioned here refers to the plane perpendicular to the second direction Z, and the meanings indicated by other planes herein are also the same as here.

In the present application, the display panel 10 includes a plurality of sub-pixels 20 on the substrate 11. Meanwhile, each film layer of the display panel 10 is formed as a whole layer through the evaporation process, and then, the hole injection layer 13 formed as a whole layer by the evaporation process is prone to have electrical connection relationship between the hole injection layers 13 at different sub-pixels 20 due to integral formation. And, the hole injection layer 13 has the characteristic of high charge carrier mobility. Therefore, charge carriers transmitted in the hole injection layers 13 of different sub-pixels 20 are easy to flow laterally in the hole injection layer 13 having an electrical connection relationship due to integral formation, such that the charge carriers may flow laterally in the hole injection layer 13 formed as a whole layer. Then, because the charge carriers flow laterally in the hole injection layer 13, the charge carriers transmitted in the hole injection layer 13 of each sub-pixel 20 are easily transmitted to each other, resulting in crosstalk of charge carriers transmitted in the hole injection layer 13 of each sub-pixel 20, a problem of lateral current leakage is easily generated between respective sub-pixels 20, and furthermore, the problem of lateral current leakage between respective sub-pixels 20 easily leads to a problem of substandard electrical crosstalk and low color gamut in a product.

It can be learned from the above embodiments that, the second hole injection sub-portion 132 is in the inner cut-off region 102, the first hole injection sub-portion 131 is in the partition region 101, the distance between the substrate 11 and the second hole injection sub-portion 132 in the inner cut-off region 102 is smaller than the distance between and the substrate 11 the first hole injection sub-portion 131 in the partition region 101, and the first hole injection sub-portion 131 is separated from the second hole injection sub-portion 132. Therefore, the portions of the hole injection layer 13 in different regions are not on the same plane, i.e., the first hole injection sub-portion 131 in the partition region 101 and the second hole injection sub-portion 132 in the inner cut-off region 102 are not on the same plane, such that the first hole injection sub-portion 131 and the second hole injection sub-portion 132 form a “recess”-shaped structure. Furthermore, because the portions of the hole injection layer 13 in different regions are not on the same plane, there is a height difference between the first hole injection sub-portion 131 and the second hole injection sub-portion 132 in the second direction Z. Due to the exist of the height difference in the second direction Z, when the first hole injection sub-portion 131 and the second hole injection sub-portion 132 are formed, the first hole injection sub-portion 131 and the second hole injection sub-portion 132 can be separated without being electrically connected, therefore, through a “recess”-shaped structure formed by the first hole injection sub-portion 131 and the second hole injection sub-portion 132, the current flowing in the hole injection layers 13 having an electrical connection relationship between the sub-pixels 20 may be blocked. Further, it may avoid crosstalk between the currents generated by the hole injection layer 13 of each sub-pixel 20, so as to avoid the problem of lateral current leakage between respective sub-pixels 20, and it may also avoid the problem of substandard electrical crosstalk and low color gamut in a product caused by lateral current leakage between respective sub-pixels 20.

It should be noted that, although each film layer of the display panel 10 is formed as a whole layer through the evaporation process, the portion of the light-emitting layer 16 in the partition region 101 does not emit light because the first hole injection sub-portion 131 is separated from the second hole injection sub-portion 132. Therefore, the portion of the light-emitting layer 16 in the partition region 101 does not emit lights but is only formed by evaporating a whole layer at the time of formation, which facilitates the preparation of the film layers of the display panel 10.

In some embodiments, as illustrated in FIG. 1, the display panel 10 further includes an anode 17. At least a portion of the anode 17 is in the inner cut-off region 102. The anode 17 is also between the hole injection layer 13 and the substrate 11, and the anode 17 is also between the second hole injection sub-portion 132 and the substrate 11. The anode 17 is electrically connected with the second hole injection sub-portion 132. At least a portion of the anode 17 is in the inner cut-off region 102, i.e., the anode 17 may be partially in the inner cut-off region 102 or entirely in the inner cut-off region 102.

Because the charge carriers flow laterally in the hole injection layer 13 formed as a whole layer, the charge carriers transmitted in the respective hole injection layers 13 of sub-pixels 20 are easily transmitted to each other, resulting in crosstalk of charge carriers transmitted in the respective hole injection layers 13 of sub-pixels 20. Thus, a problem of lateral current leakage is easily generated between respective sub-pixels 20, such that the anode 17 is unable to accurately control its corresponding light-emitting layer 16. Further, the problem of lateral current leakage between respective sub-pixels 20 easily leads to a problem of substandard electrical crosstalk and low color gamut in a product.

With the electrical connection between the second hole injection sub-portion 132 and the anode 17, it may be ensured that the first hole injection sub-portion 131 and the second hole injection sub-portion 132 form a “recess”-shaped structure. Meanwhile, the “recess”-shaped structure formed between respective sub-pixels 20 in the display panel 10 may disconnect the first hole injection sub-portion 131 from the second hole injection sub-portion 132, so as to block the transmission of the charge carriers in the hole injection layer 13. Therefore, the charge carriers transmitted from the anode 17 to the hole injection layer 13 may be prevented from being transmitted to other light-emitting layers 16, and the other light-emitting layers 16 here refer to other light-emitting layers 16 except the light-emitting layer 16 corresponding to the anode 17. Thus, the current leakage generated by the respective hole injection layers 13 of sub-pixels 20 may be prevented from crosstalk, to avoid the problem of lateral current leakage between respective sub-pixels 20, such that the anode 17 may accurately control the light-emitting layer 16 corresponding thereto. Further, it may also avoid the problem of substandard electrical crosstalk and low color gamut in a product caused by lateral current leakage between respective sub-pixels 20.

In some examples, an area of the anode 17 in the inner cut-off region 102 is greater than an area of the anode in the partition region 101. For example, the area of the anode 17 in the inner cut-off region 102 is 3˜5 times the area of the anode 17 in the partition region 101. In this way, the anode 17 may accurately control the light-emitting layer 16 corresponding thereto. Further, it may also avoid the problem of substandard electrical crosstalk and low color gamut in a product caused by lateral current leakage between respective sub-pixels 20.

In some embodiments, as illustrated in FIG. 1, the display panel 10 further includes a step structure 18. The step structure 18 is between the first hole injection sub-portion 131 and the substrate 11.

The first hole injection sub-portion 131 is on the step structure 18 and away from the substrate 11, and the step structure 18 includes at least one step 181. A portion of the second hole injection sub-portion 132 is on a surface of the at least one step 181 and away from the substrate 11, and the step structure is configured to ensure that the second hole injection sub-portions 132 on the at least one step 181 and away from the substrate 11 are separated from each other and that the first hole injection sub-portion 131 is separated from the second hole injection sub-portions 132.

In some embodiments, the steps 181 may include a first step 182. The first step 182 further includes a first upper insulation layer 1821, a first middle insulation layer 1822, and a first lower insulation layer 1823. A material of the first upper insulation layer 1821 and a material of the first lower insulation layer 1823 may include silicon oxide, and a material of the first middle insulation layer 1822 may include silicon nitride. A longer portion of the length of the first lower insulation layer 1823 in the first direction X longer than that of the first upper insulation layer 1821 in the first direction X is an outer edge portion. The length of the outer edge portion in the first direction X is greater than or equal to 0.15 microns and less than or equal to 0.35 microns. For example, the length of the outer edge portion in the first direction X may be 0.15 microns, or, the length of the outer edge portion in the first direction X may be 0.2 microns, or, the length of the outer edge portion in the first direction X may be 0.25 microns, or, the length of the outer edge portion in the first direction X may be 0.3 microns, or, the length of the outer edge portion in the first direction X may be 0.35 microns, but is not limited thereto. The length of the outer edge portion in the first direction X is greater than or equal to 0.15 microns, which may ensure that the step 181 may effectively shield the electrical instability caused by edge deformation during the deposition process, while the length of the outer edge portion in the first direction X is less than or equal to 0.35 microns to ensure that a total projected area of the outer edge portion is less than 15% of a projected area of the partition region. It should be noted that, although in the first step 182 illustrated in FIG. 1, the thicknesses of the first upper insulation layer 1821, the first middle insulation layer 1822, and the first lower insulation layer 1823 are substantially the same. However, FIG. 1 is only for the convenience of intuitively showing the film layer structure. In fact, the thickness of the first middle insulation layer 1822 is far thicker than that of the first upper insulation layer 1821 or the first lower insulation layer 1823. The film layer structures of the step 181 illustrated in other embodiments may also refer to the description here.

The step structure 18 may further include a buffer layer 180 between the step structure 18 and the anode 17. Since the material of the step structure 18 on the buffer layer 180 and away from the substrate 11 includes silicon oxide, a highly oxidizing gas is needed to use when depositing silicon oxide. And the buffer layer 180 is configured to, when depositing to form the step structure 18, avoid a reduction reaction between the highly oxidizing gas and the material of the anode 17 to affect the performance of the anode 17. After a film layer whose material includes silicon oxide is formed, the buffer layer 180 may be etched to prevent the buffer layer 180 from affecting the electrical connection relationship between the second hole injection sub-portion 132 and the anode 17.

By providing the step structure 18, a portion of the second hole injection sub-portion 132 is on the step 181 and away from the substrate 11, and through the step structure 18, it is ensured that the second hole injection sub-portions 132 on the steps 181 away from the substrate 11 are separated from each other and that the first hole injection sub-portion 131 is separated from the second hole injection sub-portion 132. Thus, by providing the step structure 18, when the hole injection layer 13 is formed, the hole injection layer 13 may be separated into the second hole injection sub-portion 132 and the first hole injection sub-portion 131 which are not electrically connected. Further, it may avoid the crosstalk of current leakage generated by the respective hole injection layers 13 of sub-pixels 20, so as to avoid the problem of lateral current leakage between respective sub-pixels 20, and at the same time, it may avoid the problem of substandard electrical crosstalk and low color gamut caused by lateral current leakage between each sub-pixel 20.

In some embodiments, as illustrated in FIG. 1, the step 181 includes an inner recess 1814, and the inner recess 1814 is a portion of the step 181 being recessed along a direction from the inner cut-off region 102 towards the partition region 101. The inner recess 1814 is between the step 181 and the second hole injection sub-portion 132. The inner recess 1814 is arranged corresponding to the second hole injection sub-portion 132.

In some embodiments, taking an embodiment illustrated in FIG. 1 as an example, the step 181 may include the first step 182. The step 182 may include a first inner recess 1824. The first inner recess 1824 is a portion of the step 182 being recessed along a direction from the inner cut-off region 102 towards the partition region 101, i.e., the first inner recess 1824 is a portion of the step 182 being recessed along the first direction X. In addition, in the first upper insulation layer 1821, the first middle insulation layer 1822, and the first lower insulation layer 1823 corresponding to the first inner recess 1824, the first middle insulation layer 1822 is recessed along the first direction X, such that the first middle insulation layer 1822 is more recessed in the first direction X than the first upper insulation layer 1821 and the first lower insulation layer 1823 to form a recessed structure, i.e., the first inner recess 1824.

Within the first inner recess 1824 is a void, i.e., the first inner recess 1824 is not filled with other materials, which maintains the void. Then in the subsequent formation of a film layer (e.g., the hole injection layer 13) on the step structure 18 and away from the substrate 11, it is difficult for ions to enter the recessed portion of the first step 182 along the second direction Z during evaporation. Therefore, no film layers are formed within the first inner recess 1824. Through the first inner recess 1824 maintaining the void therewithin, when the second hole injection sub-portion 132 is formed, the film layer material has a tendency to fill the first inner recess 1824 to generate a shear force at the inner recess 1824, such that it may be ensured that the step structure 18 separates the second hole injection sub-portions 132 on the step 181 away from the substrate 11 and that the first hole injection sub-portion 131 is separated from the second hole injection sub-portion 132. Further, it may avoid crosstalk between the current leakages generated by the respective hole injection layers 13 of sub-pixels 20, so as to avoid the problem of lateral current leakage between respective sub-pixels 20, and at the same time, it may avoid the problem of substandard electrical crosstalk and low color gamut caused by lateral current leakage between respective sub-pixels 20.

In some embodiments, as illustrated in FIG. 1, the display panel 10 further includes: at least two light-emitting layers 16 and at least one charge generation layer 15. Each of the at least two light-emitting layers 16 and the at least one charge generation layer 15 is on the hole injection layer 13 and away from the substrate 11.

Each charge generation layer 15 includes a first charge generation sub-portion 1501 and a second charge generation sub-portion 1502. The first charge generation sub-portion 1501 is in the partition region 101, and the second charge generation sub-portion 1502 is in the inner cut-off region 102. In the direction away from the substrate 11, the light-emitting layers 16 and the second charge generation sub-portion 1502 are arranged alternately. And in the direction away from the substrate 11, both the first film layer and the last film layer are the light-emitting layers 16. The distance between the second charge generation sub-portion 1502 and the substrate 11 is smaller than the distance between the first charge generation sub-portion 1501 and the substrate 11, and the first charge generation sub-portion 1501 is separated from the second charge generation sub-portion 1502.

In some embodiments, according to an embodiment illustrated in FIG. 1, the display panel 10 may include three light-emitting layers 16 and two charge generation layers 15. The display panel 10 may include a first charge generation layer 151, a second charge generation layer 152, a first light-emitting layer 161, a second light-emitting layer 162, and a third light-emitting layer 163. The first charge generation layer 151 further includes a third charge generation sub-portion 1511 and a fourth charge generation sub-portion 1512, and the second charge generation layer 152 further includes a fifth charge generation sub-portion 1521 and a sixth charge generation sub-portion 1522. The third charge generation sub-portion 1511 and the fifth charge generation sub-portion 1521 are in the partition region 101, and the fourth charge generation sub-portion 1512 and the sixth charge generation sub-portion 1522 are in the inner cut-off region 102.

For example, the distance between the third charge generation sub-portion 1511 and the fifth charge generation sub-portion 1521 is smaller than the distance between the fourth charge generation sub-portion 1512 and the sixth charge generation sub-portion 1522. Such a design is beneficial to ensure the efficient transport of charges in a plurality of light-emitting layers between the first charge generation layer 151 and the second charge generation layer 152, while slowing down the transport in the inner cut-off region 102.

Arranging the first charge generation layer 151 and the second charge generation layer 152 may implement the stacked display, i.e., in the second direction Z, through the first charge generation layer 151 and the second charge generation layer 152, the first light-emitting layer 161, the second light-emitting layer 162, and the third light-emitting layer 163, which are arranged in a stack, are connected in series to emit light, so as to improve the display efficiency and peak brightness. In addition, in this embodiment, the first light-emitting layer 161, the second light-emitting layer 162, and the third light-emitting layer 163, which are arranged in a stack, may be configured to emit red light, green light, and blue light, respectively. Specifically, the first light-emitting layer 161 may be configured to emit red light, the second light-emitting layer 162 may be configured to emit green light, and the third light-emitting layer 163 may be configured to emit blue light, which is not limited thereto in other embodiments. The three light-emitting layers 16 arranged in a stack are configured to emit light of three different colors, i.e., red light, green light, and blue light, such that the three types of light may be mixed in color, and thus, the lights emitted by the three light-emitting layers 16 arranged in a stack as a whole is white light.

It should be noted that, the display panel 10 including three light-emitting layers 16 and two charge generation layers 15 is only one feasible embodiment, which is not limited thereto in other embodiments, and the quantity of layers of the light-emitting layers 16 and the charge generation layers 15 included in the display panel 10 may be set according to actual needs.

In the present application, the display panel 10 includes sub-pixels 20 on the substrate 11. Meanwhile, each film layer of the display panel 10 is formed as a whole layer through the evaporation process, and then, the hole injection layer 13 and the charge generation layers 15 formed as whole layers by the evaporation process are prone to have electrical connection relationship between the hole injection layers 13 at different sub-pixels 20, or, between the charge generation layers 15 at different sub-pixels 20, due to integral formation. And, both the hole injection layer 13 and the charge generation layer 15 have the characteristic of high charge carrier mobility. Therefore, charge carriers transmitted in the hole injection layers 13 of different sub-pixels 20 are easy to flow laterally in the hole injection layer 13 or the charge generation layer 15 having an electrical connection relationship due to integral formation, such that the charge carriers may flow laterally in the hole injection layer 13 or the charge generation layer 15 formed as a whole layer. Then, because the charge carriers flow laterally in the hole injection layer 13 or the charge generation layer 15, the charge carriers transmitted in the hole injection layer 13 or the charge generation layer 15 of each sub-pixel 20 are easily transmitted to each other, resulting in crosstalk of charge carriers transmitted in the hole injection layer 13 or the charge generation layer 15 of each sub-pixel 20, such that a problem of lateral current leakage is easily generated between respective sub-pixels 20, and furthermore, the problem of lateral current leakage between respective sub-pixels 20 easily leads to a problem of substandard electrical crosstalk and low color gamut in a product.

The portions of the hole injection layer 13 in different regions are not on the same plane, i.e., the first hole injection sub-portion 131 in the partition region 101 and the second hole injection sub-portion 132 in the inner cut-off region 102 are not on the same plane, such that the first hole injection sub-portion 131 and the second hole injection sub-portion 132 form a “recess”-shaped structure. Similarly, the third charge generation sub-portion 1511 and the fourth charge generation sub-portion 1512, as well as the fifth charge generation sub-portion 1521 and the sixth charge generation sub-portion 1522, form “recess”-shaped structures. With the “recess”-shaped structures, the first hole injection sub-portion 131 and the second hole injection sub-portion 132 are separated without being electrically connected, the third charge generation sub-portion 1511 and the fourth charge generation sub-portion 1512 are separated without being electrically connected, the fifth charge generation sub-portion 1521 and the sixth charge generation sub-portion 1522 are separated without being electrically connected, such that the current flowing in the hole injection layers 13 or the charge generation layer 15 having an electrical connection relationship between the sub-pixels 20 may be blocked. Further, it may avoid crosstalk between the currents generated by the respective hole injection layers 13 of sub-pixels 20, thereby further avoiding the problem of lateral current leakage between respective sub-pixels 20, and at the same time, it may also avoid the problem of substandard electrical crosstalk and low color gamut in a product caused by lateral current leakage between respective sub-pixels 20.

In some embodiments, as illustrated in FIG. 1, the display panel 10 further includes: a cathode 12, an electron injection layer 14, an encapsulation layer 21, a driving array 22, and a planarization layer 23. The electron injection layer 14 is on the third light-emitting layer 163 and away from the substrate 11. The cathode 12 is on the electron injection layer 14 and away from the substrate 11. The encapsulation layer 21 is on the cathode 12 and away from the substrate 11. The encapsulation layer 21 is configured to encapsulate the film layer structure of the display panel 10, so as to prevent substances such as oxygen and water vapor from entering the film structure of the display panel 10 and causing damage to the display panel 10, and at the same time, the encapsulation layer 21 provides protection to the film layer structure of the display panel 10.

The driving array 22 is between the anode 17 and the substrate 11. The anode 17 is electrically connected with the driving array 22, and the driving array 22 is configured to transmit driving signals. When executing the driving signal indicating light emission, the driving array 22 controls the anode 17 to transport charge carriers into the hole injection layer 13. Meanwhile, the driving array 22 is configured to reflect the light incident on the driving array 22. The planarization layer 23 is between the step structure 18 and the substrate 11, and in the first direction X, the planarization layer 23 is adjacent to the anode 17. In the present application, since the thickness of the anode 17 is thick, in the second direction Z, a relatively large height difference is likely to be generated, i.e., a distance between the surface of the anode 17 away from the substrate 11 and the substrate 11 in the second direction Z is large. A relatively large height difference easily causes problems such as film layer breakage in the display panel 10, thereby affecting the normal display of the display panel 10. The planarization layer 23 is configured to fill the portion between the step structure 18 and the substrate 11, so as to achieve the effect that the surface of the planarization layer 23 away from the substrate 11 is flush with the surface of the anode 17 away from the substrate 11, thereby avoiding a large height difference to damage the film layer, for example, the step structure 18, on the planarization layer 23 and away from the substrate 11. It should be noted that, in the present application, the planarization layer 23 is configured to fill the portion between the step structure 18 and the substrate 11, so as to achieve the effect that the surface of the planarization layer 23 away from the substrate 11 is flush with the surface of the anode 17 away from the substrate 11, but it is not limit thereto in other embodiments. The surface of the planarization layer 23 away from the substrate 11 may not be flush with the surface of the anode 17 away from the substrate 11, as long as it may be ensured that the height difference between the surface of the planarization layer 23 away from the substrate 11 and the surface of the anode 17 away from the substrate 11 may avoid damage to the film layer on the planarization layer 23 and away from the substrate 11.

In some embodiments, a structure diagram of a light-emitting unit of a display panel 10 is illustrated in FIG. 2, the light-emitting unit includes: an electron injection layer 14, a first light-emitting layer 161, a second light-emitting layer 162, a third light-emitting layer 163, a first charge generation layer 151, a second charge generation layer 152, and a hole injection layer 13. As illustrated in FIG. 2, the first light-emitting layer 161 includes: a first hole transport layer 1611, a first composite light-emitting layer 1612, and a first electron transport layer 1613. The second light-emitting layer 162 includes: a second hole transport layer 1621, a second composite light-emitting layer 1622, and a second electron transport layer 1623. The third light-emitting layer 163 includes: a third hole transport layer 1631, a third composite light-emitting layer 1632, and a third electron transport layer 1633.

A first charge generation layer 151 is provided between the first electron transport layer 1613 and the second hole transport layer 1621, and the first electron transport layer 1613 and the second hole transport layer 1621 are electrically connected through the first charge generation layer 151, such that the first light-emitting layer 161 and the second light-emitting layer 162 are electrically connected. A second charge generation layer 152 is provided between the second electron transport layer 1623 and the third hole transport layer 1631, and the second electron transport layer 1623 and the third hole transport layer 1631 are electrically connected through the second charge generation layer 152, such that the second light-emitting layer 162 and the third light-emitting layer 163 are electrically connected.

When a sub-pixel 20 emits light, the cathode 12 transports electrons to the electron injection layer 14, and the anode 17 transports holes to the hole injection layer 13. And the input charge carriers cause the first charge generation layer 151 and the second charge generation layer 152 to generate electrons and holes. The first charge generation layer 151 generates electrons that are transported through the first electron transport layer 1613 to the first composite light-emitting layer 1612, while the first charge generation layer 151 generates holes that are transported through the second hole transport layer 1621 to the second composite light-emitting layer 1622. It should be noted that, although the flow direction of electrons and holes generated by the first charge generation layer 151 is described here, the flow direction of electrons and holes generated by the second charge generation layer 152 may refer to the first charge generation layer 151. In addition, taking the first composite light-emitting layer 1612 as an example, the first hole transport layer 1611 transports holes to the first composite light-emitting layer 1612, and the first electron transport layer 1613 transports electrons to the first composite light-emitting layer 1612. The holes and electrons recombine in the first composite light-emitting layer 1612 to form excitons and release energy, which causes the first composite light-emitting layer 1612 to emit light. It should be also noted that, although the light-emitting principle of the first composite light-emitting layer 1612 is described here, the light-emitting principles of the second composite light-emitting layer 1622 and the third composite light-emitting layer 1632 may refer to the first composite light-emitting layer 1612.

It should be noted that, in FIG. 1, the inner cut-off region 102 mainly illustrates the inner cut structure, and for clarity of illustration, the portion of the light-emitting layer 16 in the inner cut-off region 102 is not illustrated. However, since it is formed as a whole layer, the film layer structure of the light-emitting layer 16 in the inner cut-off region 102 is the same as the film layer structure of the light-emitting layer 16 in the partition region 101, which may refer to each other.

In some embodiments, the display panel 10 further includes a step structure 18. The step structure 18 is between the first hole injection sub-portion 131 and the substrate 11.

The first hole injection sub-portion 131 is on the step structure 18 and away from the substrate 11, and the step structure 18 includes at least one step 181. A portion of the second hole injection sub-portion 132 is on the surface of the step 181 away from the substrate 11, and the step structure 18 is configured to ensure that the second hole injection sub-portions 132 on the at least one step 181 away from the substrate 11 are separated from each other and that the first hole injection sub-portion 131 is separated from the second hole injection sub-portions 132.

The second charge generation sub-portion 1502 is on the second hole injection sub-portion 132 and away from the substrate 11, and a portion of the second charge generation sub-portion 1502 is on the step 181 and away from the substrate 11. The step structure 18 is configured to ensure that the second charge generation sub-portions 1502 on the at least one step 181 away from the substrate 11 are separated from each other and that the first hole injection sub-portion 131 is separated from the second hole injection sub-portions 132.

In some embodiments, according to an embodiment illustrated in FIG. 1, the display panel 10 may include two charge generation layers 15, i.e., the display panel 10 may include the first charge generation layer 151 and the second charge generation layer 152. The first charge generation layer 151 further includes a third charge generation sub-portion 1511 and a fourth charge generation sub-portion 1512, and the second charge generation layer 152 further includes a fifth charge generation sub-portion 1521 and a sixth charge generation sub-portion 1522. The third charge generation sub-portion 1511 and the fifth charge generation sub-portion 1521 are in the partition region 101, and the fourth charge generation sub-portion 1512 and the sixth charge generation sub-portion 1522 are in the inner cut-off region 102.

The fourth charge generation sub-portion 1512 is on the second hole injection sub-portion 132 and away from the substrate 11, and a portion of the sixth charge generation sub-portion 1522 is on the step 181 and away from the substrate 11. The fourth charge generation sub-portions 1512 on the steps 181 away from the substrate 11 are separated from each other and separated from the third charge generation sub-portions 1511. The sixth charge generation sub-portion 1522 is on the fourth charge generation sub-portion 1512 away from the substrate 11, and a portion of the sixth charge generation sub-portion 1522 is on the step 181 away from the substrate 11. The sixth charge generation sub-portions 1522 on the steps 181 away from the substrate 11 are separated from each other and separated from the fifth charge generation sub-portions 1521.

When the step structure 18 is not provided, in the second direction Z, the second hole injection sub-portion 132 is closer to the substrate 11 than the first hole injection sub-portion 131. Therefore, a relatively large height difference is likely to exist between the second hole injection sub-portion 132 and the first hole injection sub-portion 131. Then the large height difference easily causes a portion of the second hole injection sub-portion 132 extending along the second direction Z to break, and affects the electrical connection relationship between the second hole injection sub-portion 132 and the first hole injection sub-portion 131. And the same applies to the fourth charge generation sub-portions 1512 and the sixth charge generation sub-portion 1522.

By providing the step structure 18, a portion of the second hole injection sub-portion 132, a portion of the fourth charge generation sub-portion 1512, and a portion of the sixth charge generation sub-portion 1522 are on the step 181 and away from the substrate 11. The portion of the second hole injection sub-portion 132 on the step 181 away from the substrate 11 is separated from the first hole injection sub-portion 131; the portion of the fourth charge generation sub-portion 1512 on the step 181 away from the substrate 11 is separated from the third charge generation sub-portion 1511; and the portion of the sixth charge generation sub-portion 1522 is separated from the fifth charge generation sub-portion 1521. Thus, through the step structure 18, when the hole injection layer 13 is formed, the hole injection layer 13 may be broken into the second hole injection sub-portion 132 and the first hole injection sub-portion 131 which are not electrically connected; when the first charge generation layer 151 is formed, the first charge generation layer 151 may be broken into the fourth charge generation sub-portion 1512 and the third charge generation sub-portion 1511; and when the second charge generation layer 152 is formed, the second charge generation layer 152 may be broken into the sixth charge generation sub-portion 1522 and the fifth charge generation sub-portion 1521. Further, it may avoid crosstalk between the currents generated by the respective hole injection layers 13 of sub-pixels 20, so as to avoid the problem of lateral current leakage between each sub-pixel 20, and at the same time, it may avoid the problem of substandard electrical crosstalk and low color gamut caused by lateral current leakage between each sub-pixel 20.

In some embodiments, as illustrated in FIG. 1, the total quantity of layers of the hole injection layer 13 and the charge generation layer 15 is the same as the quantity of the steps 181. And a hole injection layer 13 or a charge generation layer 15 is arranged corresponding to a step 181. According to an embodiment illustrated in FIG. 1, the display panel 10 includes one hole injection layer 13 and two charge generation layers 15, so the step structure 18 includes three steps 181.

In some embodiments, the step structure 18 may include a first step 182, a second step 183, and a third step 184, which are arranged in a stack. The first step 182 may include a first upper insulation layer 1821, a first middle insulation layer 1822, and a first lower insulation layer 1823; the second step 183 may include a second upper insulation layer 1831, a second middle insulation layer 1832, and a second lower insulation layer 1833; and the third step 184 may include a third upper insulation layer 1841, a third middle insulation layer 1842, and a third lower insulation layer 1843. In addition, the second lower insulation layer 1833 and the first upper insulation layer 1821 have the same length in the first direction X, the third lower insulation layer 1843 and the second upper insulation layer 1831 have the same length in the first direction X, and if the step structure 18 is provided with more steps 181, it can also be deduced therefrom.

The height of the first step 182, the second step 183, and the third step 184 in the second direction Z are the thickness. The thickness of the first step 182 is greater than or equal to 30 nanometers and less than or equal to 55 nanometers. For example, the thickness of the first step 182 may be 30 nanometers, or the thickness of the first step 182 may be 40 nanometers, or the thickness of the first step 182 may be 50 nanometers, or the thickness of the first step 182 may be 55 nanometers, but is not limited thereto. The total thickness of the first step 182 and the second step 183 is greater than or equal to 100 nanometers and less than or equal to 150 nanometers. For example, the total thickness of the first step 182 and the second step 183 may be 100 nanometers, or the total thickness of the first step 182 and the second step 183 may be 110 nanometers, or the total thickness of the first step 182 and the second step 183 may be 120 nanometers, or the total thickness of the first step 182 and the second step 183 may be 130 nanometers, or the total thickness of the first step 182 and the second step 183 may be 140 nanometers, or the total thickness of the first step 182 and the second step 183 may be 150 nanometers, but is not limited thereto. The total thickness of the first step 182, the second step 183, and the third step 184 is greater than or equal to 200 nanometers and less than or equal to 300 nanometers. For example, the total thickness of the first step 182, the second step 183, and the third step 184 may be 200 nanometers, or the total thickness of the first step 182, the second step 183, and the third step 184 may be 225 nanometers, or the total thickness of the first step 182, the second step 183, and the third step 184 may be 250 nanometers, or the total thickness of the first step 182, the second step 183, and the third step 184 may be 275 nanometers, or the total thickness of the first step 182, the second step 183, and the third step 184 may be 300 nanometers, but is not limited thereto.

An angle of a first included angle α between the substrate 11 and a line connecting the edges of the first step 182, the second step 183, and the third step 184 is greater than or equal to 15 degrees and less than or equal to 45 degrees. For example, the angle of the first included angle α may be 15 degrees, or the angle of the first included angle α may be 25 degrees, or the angle of the first included angle α may be 35 degrees, or the angle of the first included angle α may be 45 degrees, but is not limited thereto.

By providing the steps 181 with a quantity same as the total quantity of layers of the hole injection layer 13 and the charge generation layers 15 and that a hole injection layer 13 or a charge generation layer 15 corresponds to a step 181, it may be ensured that the hole injection layer 13 and each of the charge generation layers 15 can be separated by a step 181, and at the same time, it may avoid providing too many steps 181. Further, it can reduce costs while ensuring that the step structure 18 can effectively partition the hole injection layer 13 and partition the charge generation layer 15.

In some embodiments, each step 181 includes an inner recess 1814, and the inner recess 1814 is a portion of the step 181 being recessed along a direction away from the inner cut-off region 102. The inner recess 1814 is between the step 181 and the second hole injection sub-portion 132 corresponding to the step 181, or the inner recess 1814 is between the step 181 and the second charge generation sub-portion 1502 corresponding to the step 181.

In some embodiments, the first step 182 may include a first inner recess 1824, the second step 183 may include a second inner recess 1834, and the third step 184 may include a third inner recess 1844. The first inner recess 1824 is a portion of the step 181 being recessed along a direction from the inner cut-off region 102 towards the partition region 101, i.e., the first inner recess 1824 is a portion of the first step 182 being recessed along the first direction X. In addition, in the first upper insulation layer 1821, the first middle insulation layer 1822, and the first lower insulation layer 1823 corresponding to the first inner recess 1824, the first middle insulation layer 1822 is recessed along the first direction X, such that the first middle insulation layer 1822 is more recessed in the first direction X than the first upper insulation layer 1821 and the first lower insulation layer 1823 to form a recessed structure, i.e., the first inner recess 1824. If the step structure 18 includes more steps 181, it can also be deduced therefrom, i.e., the second inner recess 1834 and the third inner recess 1844 may also refer to the description of the first inner recess 1824.

The first inner recess 1824, the second inner recess 1834, and the third inner recess 1844 are all a void, i.e., none of the first inner recess 1824, the second inner recess 1834, and the third inner recess 1844 is filled with other materials, which maintains the void. Then in the subsequent formation of a film layer (e.g., the hole injection layer 13) on the step structure 18 away from the substrate 11, it is difficult for ions to enter the recessed portion of the first step 182 along the second direction Z during evaporation, therefore, film layers will not be formed within the first inner recess 1824, the second inner recess 1834, and the third inner recess 1844. With the first inner recess 1824, the second inner recess 1834, and the third inner recess 1844 having the voids, the hole injection layer 13 may be separated from other highly conductive film layers by the inner recess 1814, and similarly, the first charge generation layer 151 or the second charge generation layer 152 may be separated from other highly conductive film layers by the inner recess 1814. Thus, it may avoid abnormal electrical connections between the hole injection layer 13, the first charge generation layer 151, or the second charge generation layer 152 and other highly conductive film layers to affect the normal display of the display panel 10.

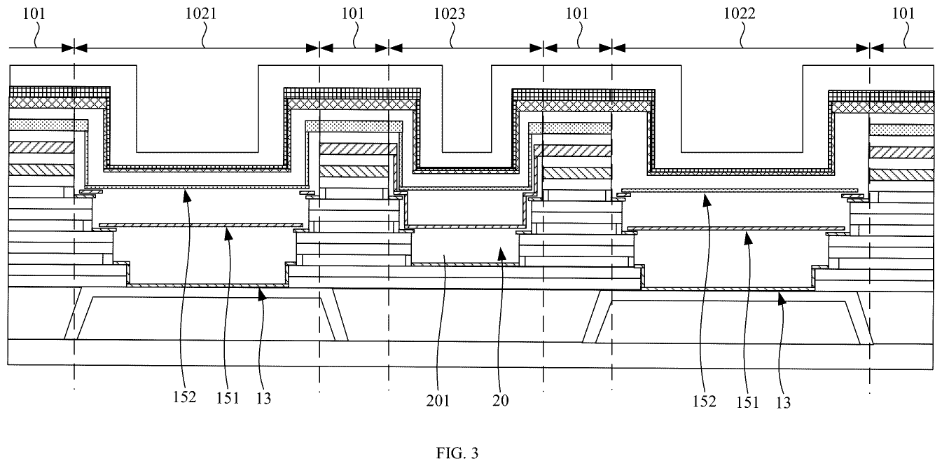

In some embodiments, FIG. 3 illustrates a structure diagram of the display panel 10. As illustrated in FIG. 3, the step structure 18 includes an inner cut portion 201 in the inner cut-off region 102, and the inner cut portion 201 is a portion of the step structure 18 being recessed towards the substrate 11. The step 181 in the inner cut portion 201 is configured to separate at least one layer of the second hole injection sub-portion 132 or the second charge generation sub-portion 1502.

In some embodiments, the step 181 in the inner cut portion 201 may only partition the second hole injection sub-portion 132, or the step 181 in the inner cut portion 201 may partition the second hole injection sub-portion 132 and partition the second charge generation sub-portion 1502 at the same time, or the step 181 in the inner cut portion 201 may partition the second hole injection sub-portion 132, partition the fourth charge generation sub-portion 1512, and partition the sixth charge generation sub-portion 1522 at the same time.

By arranging the inner cut portion 201 in the step structure 18 and the step 181 in the inner cut portion 201, at least one layer of the second hole injection sub-portion 132, the fourth charge generation sub-portion 1512, or the sixth charge generation sub-portion 1522 is partitioned. Thus, it may further block the leakage current flowing between the sub-pixels 20 and in the hole injection layers 13 or the charge generation layers 15 formed as a whole layer. Further, it may further avoid crosstalk between the leakage currents generated by the respective hole injection layers 13 of sub-pixels 20, thereby further avoiding the problem of lateral current leakage between respective sub-pixels 20, and at the same time, it may avoid the problem of substandard electrical crosstalk and low color gamut in a product caused by lateral current leakage between respective sub-pixels 20.

In some embodiments, as illustrated in FIG. 3, the step 181 in adjacent inner cut-off regions 102 separates at least one layer of the second hole injection sub-portion 132 or the second charge generation sub-portion 1502. Specifically, as illustrated in FIG. 3, the inner cut-off regions 102 may include a first inner cut-off region 1021, a second inner cut-off region 1022, and a third inner cut-off region 1023. The first inner cut-off region 1021 and the second inner cut-off region 1022 are both adjacent to the third inner cut-off region 1023. Meanwhile, the inner cut portion 201 of the step structure 18 may be in the third inner cut-off region 1023. The steps 181 in the first inner cut-off region 1021, the second inner cut-off region 1022, and the third inner cut-off region 1023 may be configured to partition at least one layer of the second hole injection sub-portion 132, the fourth charge generation sub-portion 1512, or the sixth charge generation sub-portion 1522, respectively.

In an embodiment illustrated in FIG. 3, the display panel 10 may include two charge generation layers 15 and one hole injection layer 13, i.e., the display panel 10 may include the first charge generation layer 151 and the second charge generation layer 152. The first charge generation layer 151 further includes a third charge generation sub-portion 1511 and a fourth charge generation sub-portion 1512, the second charge generation layer 152 further includes a fifth charge generation sub-portion 1521 and a sixth charge generation sub-portion 1522, and the hole injection layer 13 includes a first hole injection sub-portion 131 and a second hole injection sub-portion 132.

The step 181 in the first inner cut portion 1021 is configured to partition the second hole injection sub-portion 132 and partition the fourth charge generation sub-portion 1512. The step 181 in the second inner cut-off region 1022 is configured to partition the second hole injection sub-portion 132, partition the fourth charge generation sub-portion 1512, and partition the sixth charge generation sub-portion 1522. The step 181 in the third inner cut portion 1023 is configured to partition the second hole injection sub-portion 132.

By arranging the steps 181 in the first inner cut-off region 1021, the second inner cut-off region 1022, and the third inner cut-off region 1023, and each of the step 181 partitions at least one layer of the second hole injection sub-portion 132, the fourth charge generation sub-portion 1512, or the sixth charge generation sub-portion 1522, respectively, the degree of crosstalk between different sub-pixels 20 may be adjusted according to actual needs. Further, the blocking effect between each sub-pixel 20 and the surrounding sub-pixels 20 may be selected and arranged according to actual needs.

In some embodiments, the width of the first inner cut-off region 1021 is smaller than the width of the second inner cut-off region 1022 and/or the third inner cut-off region 1023. Such a design may enable the blocking effect between the sub-pixel 20 and the surrounding sub-pixels 20 to be selected and arranged according to actual needs.

In some embodiments, between adjacent sub-pixels 20, a distance between adjacent first steps 182 is less than a distance between adjacent second steps 183 and less than a distance between adjacent third steps 184. Such formed step structure is conducive to mitigating the crosstalk between different sub-pixels 20.

In some embodiments, between adjacent sub-pixels 20, a distance between adjacent buffer layers 180 is less than a distance between adjacent second lower insulation layers 1833 and less than a distance between adjacent third lower insulation layers 1843, and further less than a distance between adjacent third upper insulation layers 1841. Such a design may be conducive to mitigating the crosstalk between different sub-pixels 20.

The present application further provides an electronic device including any one of the display panel 10 described above. The electronic device may be a VR/AR device or other near-eye display device, but is not limited thereto.

The above embodiments of the present application, in the absence of conflicts, may complement each other.

It is to be noted that in the accompanying drawings, the dimensions of layers and regions may be exaggerated for clarity of illustration. It will be understood that when an element or a layer is referred to as being “above” or “on” another element or layer, it may be directly on the other element, or intervening layers may be present. In addition, it will be understood that when an element or a layer is referred to as being “under” or “below” another element or layer, it may be directly under the other element, or one or more intervening layers or elements may be present. In addition, it will also be understood that when a layer or an element is referred to as being “between” two layers or two elements, it may be the only layer between the two layers or two elements, or one or more intervening layers or elements may be present. Like reference numerals indicate like elements throughout.

The term “a plurality” indicates two or more, unless specifically defined otherwise.

Those skilled in the art will readily conceive other embodiments of the present application upon consideration of the specification and practice of the various embodiments disclosed herein. The present application is intended to cover any variation, use, or adaptive change of this application. These variations, uses, or adaptive changes follow the general principles of this application and include common general knowledge or common technical means in the art that are not disclosed in this application. The specification and the embodiments are considered as merely exemplary, and the real scope and spirit of the present application are pointed out in the following claims.

It should be understood that this application is not limited to the precise structures described above and illustrated in the accompanying drawings, and various modifications and changes may be made without departing from the scope of the present application. The scope of the present application is limited only by the appended claims.

1. A display panel, wherein the display panel has an inner cut-off region and a partition region, and the inner cut-off region is adjacent to the partition region;
the display panel comprises: a substrate, a light-emitting layer, and a hole injection layer;
a portion of the light-emitting layer in the inner cut-off region is configured to emit lights, and the light-emitting layer is on the substrate; the hole injection layer is between the light-emitting layer and the substrate, and the light-emitting layer is on the hole injection layer and away from the substrate; and
the hole injection layer comprises a first hole injection sub-portion and a second hole injection sub-portion; the first hole injection sub-portion is in the partition region; the second hole injection sub-portion is in the inner cut-off region and between the light-emitting layer and the substrate; and a distance between the second hole injection sub-portion and the substrate is smaller than a distance between the first hole injection sub-portion and the substrate, and the first hole injection sub-portion is separated from the second hole injection sub-portion.

2. The display panel according to claim 1, wherein the display panel further comprises an anode; the anode is at least partially in the inner cut-off region, the anode is between the hole injection layer and the substrate, and the anode is between the second hole injection sub-portion and the substrate; and wherein the anode is electrically connected with the second hole injection sub-portion.

3. The display panel according to claim 1, wherein the display panel further comprises a step structure, and the step structure is between the first hole injection sub-portion and the substrate; and
wherein the first hole injection sub-portion is on the step structure away from the substrate, and the step structure comprises at least one step; and a portion of the second hole injection sub-portion is on a surface of the at least one step and away from the substrate, and the step structure is configured to ensure that second hole injection sub-portions on the at least one step away from the substrate are separated from each other and that the first hole injection sub-portion is separated from the second hole injection sub-portions.

4. The display panel according to claim 3, wherein the step comprises an inner recess, and the inner recess is a portion of the step being recessed along a direction from the inner cut-off region towards the partition region; the inner recess is between the step and the second hole injection sub-portion; and
the inner recess is arranged corresponding to the second hole injection sub-portion.

5. The display panel according to claim 1, wherein the display panel further comprises: at least two light-emitting layers and at least one charge generation layer; each of the at least two light-emitting layers and the at least one charge generation layer is on the hole injection layer away from the substrate; and
wherein each of the at least one charge generation layer comprises a first charge generation sub-portion and a second charge generation sub-portion; the first charge generation sub-portion is in the partition region; the second charge generation sub-portion is in the inner cut-off region; in a direction away from the substrate, the light-emitting layer and the second charge generation sub-portion are arranged alternately, and in the direction away from the substrate, both a first film layer and a last film layer are the light-emitting layers; and a distance between the second charge generation sub-portion and the substrate is smaller than a distance between the first charge generation sub-portion and the substrate, and the first charge generation sub-portion is separated from the second charge generation sub-portion.

6. The display panel according to claim 5, wherein the display panel further comprises a step structure, and the step structure is between the first hole injection sub-portion and the substrate;
wherein the first hole injection sub-portion is on the step structure and away from the substrate, and the step structure comprises at least one step; a portion of the second hole injection sub-portion is on a surface of the at least one step and away from the substrate, and the step structure is configured to ensure that second hole injection sub-portions on the at least one step away from the substrate are separated from each other and that the first hole injection sub-portion is separated from the second hole injection sub-portions; and
the second charge generation sub-portion is on the second hole injection sub-portion and away from the substrate, and a portion of the second charge generation sub-portion is on the at least one step and away from the substrate; and the step structure is configured to ensure that second charge generation sub-portions on the at least one step away from the substrate are separated from each other and that the first hole injection sub-portion is separated from the second hole injection sub-portions.

7. The display panel according to claim 6, wherein a total quantity of the hole injection layer and the at least one charge generation layer is the same as a quantity of the steps; and one hole injection layer or one charge generation layer is arranged corresponding to one of the steps.

8. The display panel according to claim 7, wherein each of the steps comprises an inner recess, and the inner recess is a portion of the step being recessed along a direction away from the inner cut-off region; and the inner recess is between the step and the second hole injection sub-portion corresponding to the step, or, the inner recess is between the step and the second charge generation sub-portion corresponding to the step.

9. The display panel according to claim 6, wherein the step structure comprises an inner cut portion in the inner cut-off region, and the inner cut portion is a portion of the step structure being recessed towards the substrate; and the step in the inner cut portion is configured to separate at least one layer of the second hole injection sub-portion or the second charge generation sub-portion.

10. The display panel according to claim 9, wherein the step provided in adjacent inner cut-off regions separates at least one layer of the second hole injection sub-portion or the second charge generation sub-portion.

11. An electronic device, comprising a display panel,
wherein the display panel has an inner cut-off region and a partition region, and the inner cut-off region is adjacent to the partition region;
the display panel comprises: a substrate, a light-emitting layer, and a hole injection layer;
a portion of the light-emitting layer in the inner cut-off region is configured to emit lights, and the light-emitting layer is on the substrate; the hole injection layer is between the light-emitting layer and the substrate, and the light-emitting layer is on the hole injection layer and away from the substrate; and
the hole injection layer comprises a first hole injection sub-portion and a second hole injection sub-portion; the first hole injection sub-portion is in the partition region; the second hole injection sub-portion is in the inner cut-off region and between the light-emitting layer and the substrate; and a distance between the second hole injection sub-portion and the substrate is smaller than a distance between the first hole injection sub-portion and the substrate, and the first hole injection sub-portion is separated from the second hole injection sub-portion.

12. The display panel according to claim 11, wherein the display panel further comprises an anode; the anode is at least partially in the inner cut-off region, the anode is between the hole injection layer and the substrate, and the anode is between the second hole injection sub-portion and the substrate; and wherein the anode is electrically connected with the second hole injection sub-portion.

13. The display panel according to claim 11, wherein the display panel further comprises a step structure, and the step structure is between the first hole injection sub-portion and the substrate; and
wherein the first hole injection sub-portion is on the step structure away from the substrate, and the step structure comprises at least one step; and a portion of the second hole injection sub-portion is on a surface of the at least one step and away from the substrate, and the step structure is configured to ensure that second hole injection sub-portions on the at least one step away from the substrate are separated from each other and that the first hole injection sub-portion is separated from the second hole injection sub-portions.

14. The display panel according to claim 13, wherein the step comprises an inner recess, and the inner recess is a portion of the step being recessed along a direction from the inner cut-off region towards the partition region; the inner recess is between the step and the second hole injection sub-portion; and
the inner recess is arranged corresponding to the second hole injection sub-portion.

15. The display panel according to claim 11, wherein the display panel further comprises: at least two light-emitting layers and at least one charge generation layer; each of the at least two light-emitting layers and the at least one charge generation layer is on the hole injection layer away from the substrate; and
wherein each of the at least one charge generation layer comprises a first charge generation sub-portion and a second charge generation sub-portion; the first charge generation sub-portion is in the partition region; the second charge generation sub-portion is in the inner cut-off region; in a direction away from the substrate, the light-emitting layer and the second charge generation sub-portion are arranged alternately, and in the direction away from the substrate, both a first film layer and a last film layer are the light-emitting layers; and a distance between the second charge generation sub-portion and the substrate is smaller than a distance between the first charge generation sub-portion and the substrate, and the first charge generation sub-portion is separated from the second charge generation sub-portion.

16. The display panel according to claim 15, wherein the display panel further comprises a step structure, and the step structure is between the first hole injection sub-portion and the substrate;
wherein the first hole injection sub-portion is on the step structure and away from the substrate, and the step structure comprises at least one step; a portion of the second hole injection sub-portion is on a surface of the at least one step and away from the substrate, and the step structure is configured to ensure that second hole injection sub-portions on the at least one step away from the substrate are separated from each other and that the first hole injection sub-portion is separated from the second hole injection sub-portions; and
the second charge generation sub-portion is on the second hole injection sub-portion and away from the substrate, and a portion of the second charge generation sub-portion is on the at least one step and away from the substrate; and the step structure is configured to ensure that second charge generation sub-portions on the at least one step away from the substrate are separated from each other and that the first hole injection sub-portion is separated from the second hole injection sub-portions.

17. The display panel according to claim 16, wherein a total quantity of the hole injection layer and the at least one charge generation layer is the same as a quantity of the steps; and one hole injection layer or one charge generation layer is arranged corresponding to one of the steps.

18. The display panel according to claim 17, wherein each of the steps comprises an inner recess, and the inner recess is a portion of the step being recessed along a direction away from the inner cut-off region; and the inner recess is between the step and the second hole injection sub-portion corresponding to the step, or, the inner recess is between the step and the second charge generation sub-portion corresponding to the step.

19. The display panel according to claim 16, wherein the step structure comprises an inner cut portion in the inner cut-off region, and the inner cut portion is a portion of the step structure being recessed towards the substrate; and the step in the inner cut portion is configured to separate at least one layer of the second hole injection sub-portion or the second charge generation sub-portion.

20. The display panel according to claim 19, wherein the step provided in adjacent inner cut-off regions separates at least one layer of the second hole injection sub-portion or the second charge generation sub-portion.
